(19) United States
(12) Patent Application Publication
(10) Pub. No.: US 2026/0353941 A1
(43) Pub. Date: Nov. 5, 2026

(54) DISPLAY PANEL AND DISPLAY DEVICE

(71) Applicants: Chengdu BOE Optoelectronics Technology Co., Ltd., Sichuan (CN); BOE TECHNOLOGY GROUP CO., LTD., Beijing (CN)

(72) Inventors: Qian XU, Beijing (CN); Yan HUANG, Beijing (CN)

(21) Appl. No.: 19/487,511

(22) PCT Filed: May 20, 2024
(86) PCT No.: PCT/CN2024/094204

§ 371 Date: Nov. 25, 2025

(30) Foreign Application Priority Data
Jun. 20, 2023 (CN) 202310735708.0

(51) Int. Cl. H10K 59/124; H10K 59/122

(52) U.S. Cl. CPC H10K 59/124; H10K 59/122

(57) ABSTRACT

The present disclosure relates to a display panel. The display panel includes a functional layer group; the side of the functional layer group away from a base substrate includes at least one pattern-to-be-formed area and other area; the other area is located on the periphery of the pattern-to-be-formed area; at least some of the other area is higher than the pattern-to-be-formed area; and the distance between the at least some of the other area and the substrate is greater than the distance between the pattern-to-be-formed area and the substrate. A step is formed between the other area and the pattern-to-be-formed area, and the pattern-to-be-formed area is not scratched when a fine mask moves. The present disclosure further provides a display device comprising the display panel.

### CROSS-REFERENCE TO RELATED APPLICATIONS

The present disclosure is a U.S. National Stage of International Application No. PCT/CN2024/094204, filed on May 20, 2024, which claims priority to Chinese patent application number 202310735708.0, filed on Jun. 20, 2023, entitled “Display Panel and Display Device”, both of which are incorporated herein by reference in their entireties for all purposes.

### TECHNICAL FIELD

The present disclosure relates to the field of display technology, and in particular to a display panel and a display device.

### BACKGROUND

By monitoring the offset of the center of the pattern-to-be-formed area relative to the alignment mark center, the overall offset of the fine metal mask can be estimated.

During fluctuation of the fine metal mask, it can easily scrape against the pattern-to-be-formed area on the backplane. This generates particulate contaminants on the pattern-to-be-formed area, which reduces the identification accuracy of the testing device and affects the evaporation yield.

It should be noted that the information disclosed in the above background section is intended only to enhance understanding of the background of the present disclosure and, therefore, may include information that does not constitute prior art known to those skilled in the art.

### SUMMARY

According to an aspect of the present disclosure, there is provided a display panel including a display area and a non-display area peripherally surrounding the display area, where the display panel includes a substrate and a functional layer group; the functional layer group is disposed on a side of the substrate, the functional layer group includes at least one pattern-to-be-formed area and other area on a side away from the substrate, the at least one pattern-to-be-formed area is located in the non-display area, the other area peripherally surrounds the pattern-to-be-formed area, and a distance between at least part of the other area and the substrate is greater than a distance between the pattern-to-be-formed area and the substrate.

In an embodiment of the present disclosure, the functional layer group includes a planarization layer group, a first electrode and a pixel definition layer; the planarization layer group includes a first planarization layer and a second planarization layer, the first planarization layer is disposed on a side of the substrate, and the second planarization layer is located on a side of the first planarization layer away from the substrate; the first electrode is disposed on a side of the planarization layer group away from the substrate; the pixel definition layer is disposed on a side of the first electrode away from the substrate, the pixel definition layer is provided with a pixel opening, and the pixel opening exposes the first electrode.

In an embodiment of the present disclosure, the other area includes an alignment pattern area, the alignment pattern area is located in the non-display area and adjacent to the pattern-to-be-formed area, the functional layer group includes an alignment pattern, and an orthographic projection of the alignment pattern on the substrate is at least partially located within an orthographic projection of the alignment pattern area on the substrate.

In an embodiment of the present disclosure, the other area further includes a support area, the support area peripherally surrounds the alignment pattern area, a distance between the support area and the substrate is greater than a distance between the pattern-to-be-formed area and the alignment pattern area and the substrate.

In an embodiment of the present disclosure, the alignment pattern and the first electrode are formed on the same layer and with the same material.

In an embodiment of the present disclosure, the functional layer group further includes a spacer layer, the spacer layer is located on a side of the pixel definition layer away from the substrate, the spacer layer comprises a support portion, the pattern-to-be-formed area is located on a side of the pixel definition layer away from the substrate, and the support area is located on a side of the support portion away from the substrate.

In an embodiment of the present disclosure, the functional layer group is provided with a first opening in the non-display area, the first opening at least partially passes through the pixel definition layer, the pattern-to-be-formed area is located within the first opening, and the alignment pattern area is located on a surface of the pixel definition layer away from the substrate.

In an embodiment of the present disclosure, the first opening includes a first opening segment passing through the pixel definition layer, or a first opening segment passing through the pixel definition layer and a second opening segment passing through the second planarization layer, an orthographic projection of the first opening segment on the substrate coincides with an orthographic projection of the second opening segment on the substrate.

In an embodiment of the present disclosure, the functional layer group is provided with a second opening in the non-display area, the second opening at least partially passes through the pixel definition layer, the pattern-to-be-formed area and the alignment pattern area are both located within the second opening, and the support area is located on a side of the pixel definition layer away from the substrate.

In an embodiment of the present disclosure, the functional layer group further includes a source/drain metal layer, the source/drain metal layer is located between the first planarization layer and the substrate, and/or between the first planarization layer and the second planarization layer, and the alignment pattern is formed on the same layer and with the same material as the source/drain metal layer.

In an embodiment of the present disclosure, the functional layer group is provided with a third opening in the non-display area, the third opening at least partially passes through the second planarization layer, the pattern-to-be-formed area and the alignment pattern area are both located within the third opening, the third opening includes a first sub-opening area and a second sub-opening area, the alignment pattern is located in the first sub-opening area, the pixel definition layer covers the second sub-opening area, and covers the alignment pattern and a side of the second planarization layer away from the substrate, an orthographic projection of the alignment pattern area on the pixel definition layer overlaps with an orthographic projection of the first sub-opening area on the pixel definition layer, and an orthographic projection of the pattern-to-be-formed area on the pixel definition layer overlaps with an orthographic projection of the second sub-opening area on the pixel definition layer.

In an embodiment of the present disclosure, the non-display area includes an identification area, the alignment pattern and the pattern-to-be-formed area constitute a pattern group to be identified, the pattern group to be identified is located within the identification area, and the support portion is disposed around the pattern group to be identified, and the support portion is located outside or within the identification area.

In an embodiment of the present disclosure, when the support portion is located outside the identification area, a distance between the support portion and an edge of the identification area is less than 1 mm.

In an embodiment of the present disclosure, a dimension of the support portion along a first direction is unequal to a dimension of the support portion along a second direction, the first direction and the second direction are both located on a surface of the substrate, and the second direction is perpendicular to the first direction.

In an embodiment of the present disclosure, the dimension of the support portion along the first direction is 50 μm to 100 μm.

In an embodiment of the present disclosure, a height difference between the support area and the pattern-to-be-formed area is 1 μm to 2 μm.

In an embodiment of the present disclosure, the support portion is provided with at least one first groove, and the first groove extends in the same direction as the support portion.

In an embodiment of the present disclosure, the support portion is a continuous and closed structure, and an orthographic projection of the support portion on the substrate is an elliptical, circular, or polygonal shape.

In an embodiment of the present disclosure, the support portion includes at least one set of support segments, one set of support segments includes two support segments, and the two support segments are arranged parallel to opposite sides of the identification area.

In an embodiment of the present disclosure, the support portion includes a plurality of support blocks, the plurality of support blocks are distributed along an outline of the identification area.

In an embodiment of the present disclosure, orthographic projections of the support blocks on the substrate are rectangular, circular, or polygonal shapes.

In an embodiment of the present disclosure, the pattern-to-be-formed area includes multiple figure-to-be-formed regions, the multiple figure-to-be-formed regions are arranged sequentially along a first direction, and the alignment pattern comprises at least one first alignment mark, a plurality of second alignment marks and a third alignment mark; the at least one first alignment mark is arranged along the first direction and located on the same straight line with the multiple figure-to-be-formed regions; the plurality of second alignment marks are arranged along a second direction, the second direction intersects the first direction, and the multiple second alignment marks are located on the same straight line with the multiple figure-to-be-formed regions along the second direction respectively; the third alignment mark is arranged at an intersection point of a line containing the first alignment mark and a line containing the second alignment mark.

In an embodiment of the present disclosure, the display panel includes multiple pattern groups to be identified, all of the multiple pattern groups to be identified are located in the display area.

In an embodiment of the present disclosure, a light-emitting functional layer is provided on a side of each of the figure-to-be-formed regions away from the substrate, and a distance between at least part of the other area and the substrate is greater than a distance between the light-emitting functional layer and the substrate.

According to another aspect of the present disclosure, there is provided a display device including the display panel according to an aspect of the present disclosure.

It should be understood that the above general description and the following detailed description are merely exemplary and illustrative and do not limit the present disclosure.

### BRIEF DESCRIPTION OF THE DRAWINGS

The accompanying drawings herein are incorporated into and constitute a part of this specification. They illustrate embodiments consistent with the present disclosure and, together with the description, serve to explain the principles of the present disclosure. It should be understood that the drawings described below represent only some embodiments of the present disclosure. Those skilled in the art can derive other drawings based on these drawings without inventive effort.

FIG. 1 is a plan view schematically illustrating the distribution of a group of patterns to be identified on a display panel according to an embodiment of the present disclosure.

FIG. 2 is a partially enlarged view of area A in FIG. 1.

FIG. 3 is a plan view schematically illustrating a positional relationship between a pattern-to-be-formed area in a group of patterns to be identified and an alignment pattern according to an embodiment of the present disclosure.

FIG. 4 is a cross-sectional view schematically illustrating a case of scratching between a fine metal mask and a backplane according to an embodiment of the present disclosure.

FIG. 5 is a cross-sectional view schematically illustrating another case of scratching between a fine metal mask and a backplane according to an embodiment of the present disclosure.

FIG. 6 is a plan view schematically illustrating scratching between a fine metal mask and a backplane according to an embodiment of the present disclosure.

FIG. 7 is a schematic cross-sectional view of a display panel according to an embodiment of the present disclosure, where a support portion is located in a spacer layer and a support region is on the side of the support portion facing away from the substrate.

FIG. 8 is a schematic cross-sectional view of a display panel according to an embodiment of the present disclosure, where a support portion is located in a pixel definition layer and a support region is on the side of the support portion facing away from the substrate.

FIG. 9 is a schematic cross-sectional view of the display panel according to FIG. 7, where a first groove is provided on the side of the support portion facing away from the substrate.

FIG. 10 is a schematic cross-sectional view of the display panel according to FIG. 8, where a first groove is provided on the side of the support portion facing away from the substrate.

FIG. 11 is a schematic plan view of a support portion according to an embodiment of the present disclosure, where the support portion surrounds a pattern group to be identified.

FIG. 12 is a schematic plan view of another support portion according to an embodiment of the present disclosure, where the support portion surrounds a pattern group to be identified.

FIG. 13 is a schematic plan view of a support portion according to an embodiment of the present disclosure, where the support portion includes two support segments, and the two support segments are arranged along a first direction.

FIG. 14 is a schematic plan view of a support portion according to an embodiment of the present disclosure, where the support portion includes two support segments, and the two support segments are arranged along a second direction.

FIG. 15 is a schematic plan view of a support portion according to an embodiment of the present disclosure, where the support portion includes multiple support blocks, and the shapes of the support blocks are rectangular.

FIG. 16 is a schematic plan view of a support portion according to an embodiment of the present disclosure, where the support portion includes multiple support blocks, and the shapes of the support blocks are circular.

FIG. 17 is a schematic cross-sectional view of a display panel according to an embodiment of the present disclosure, where a first opening is provided on the display panel and an alignment pattern is provided in the same layer as a first electrode.

FIG. 18 is a schematic cross-sectional view of a display panel according to an embodiment of the present disclosure, where a first opening is provided on the display panel and an alignment pattern is provided in the same layer as a second source electrode.

FIG. 19 is a schematic cross-sectional view of a display panel according to an embodiment of the present disclosure, where a third opening is provided on the display panel and an alignment pattern is located within the third opening.

### REFERENCE NUMERALS

1—Fine Metal Mask, 2—Display Panel, 201—Display Area, 202—Non-Display Area, 2021—Identification area, 203—Dam, 2031—First Dam, 2032—Second Dam, 20—Substrate, 21—Functional Layer Group, 211—Pattern-to-be-formed area, 2111—First figure-to-be-formed region, 2112—Second figure-to-be-formed region, 2113—Third figure-to-be-formed region, 2114—Fourth figure-to-be-formed region, 2115—Fifth figure-to-be-formed region, 212—Alignment Pattern Area, 213—Support Region, 214—Support Portion, 2141—First Groove, 2142—Support Segment, 2143—Support Block, 215—First Opening, 2151—First Opening Segment, 2152—Second Opening Segment, 216—Second Opening, 217—Third Opening, 2171—First Sub-opening Area, 2172—Second Sub-opening Area, 22—Buffer Layer, 23—Driving Circuit Layer, 231—Thin Film Transistor, 2311—Active Layer, 2312—Gate Insulation Layer, 2313—Gate, 2314—Interlayer Insulation Layer, 2315—Interlayer Dielectric Layer, 2316—First Source, 2317—Drain, 2318—Protective Layer, 2319—Second Source, 232—Alignment Pattern, 2321—First Alignment Mark, 2322—Second Alignment Mark, 2323—Third Alignment Mark, 24—Planarization Layer Group, 241—First Planarization Layer, 242—Second Planarization Layer, 25—Pixel Definition Layer, 251—Pixel Opening, 26—Pixel Layer, 261—First Electrode, 262—Light-emitting Layer Group, 2621—Patterned Layer, 2622—Common Layer, 263—Second Electrode, 265—Light-emitting Functional Layer, 27—Encapsulation Layer, 271—First Inorganic Encapsulation Layer, 272—Organic Encapsulation Layer, 273—Second Inorganic Encapsulation Layer, 28—Spacer Layer, 281—Spacer Column, 29—Backplane.

### DETAILED DESCRIPTION

Example embodiments will now be described more fully with reference to the accompanying drawings. However, the example embodiments can be embodied in many forms and should not be construed as limited to the embodiments set forth herein; rather, these embodiments are provided so that the present disclosure will be thorough and complete and will fully convey the concepts of the example embodiments to those skilled in the art. Like reference numerals in the figures represent like or similar structures, and detailed descriptions thereof will be omitted. Furthermore, the figures are merely schematic illustrations of the present disclosure and are not necessarily drawn to scale.

While relative terms such as “upper” and “lower” are used herein to describe the relationship of one illustrated component to another, these terms are used herein for convenience only, for example, based on the orientation of the examples depicted in the figures. It should be understood that if the illustrated device were flipped upside down, the component described as “upper” would become the component “lower”. When a structure is referred to as “on” another structure, this may mean that the structure is integrally formed on another structure, that the structure is “directly” disposed on another structure, or that the structure is “indirectly” disposed on another structure via a third structure.

The terms “a”, “an”, “the”, “said” and “at least one” indicate the presence of one or more elements/components/etc.; the terms “including” and “having” are intended to be inclusive and imply that additional elements/components may be present in addition to the listed elements/components; the terms “first”, “second” and “third” are used solely as labels and do not limit the number of objects.

OLED display devices are currently primarily manufactured using a fine metal mask (FMM) to deposit the light-emitting layer (EL) on a backplane (BP) by evaporation. To ensure that all EL materials pass through the openings to be patterned in the FMM and land on the EL cells of corresponding sub-pixels on the backplane after evaporation, it needs to design a pixel position accuracy test element group (PPA Teg) to monitor the alignment accuracy of the evaporation process. The PPA Teg is configured to identify the difference between the actual evaporation position of the light-emitting functional layer and its ideal evaporation position, which can be achieved by identifying the light-emitting functional layer.

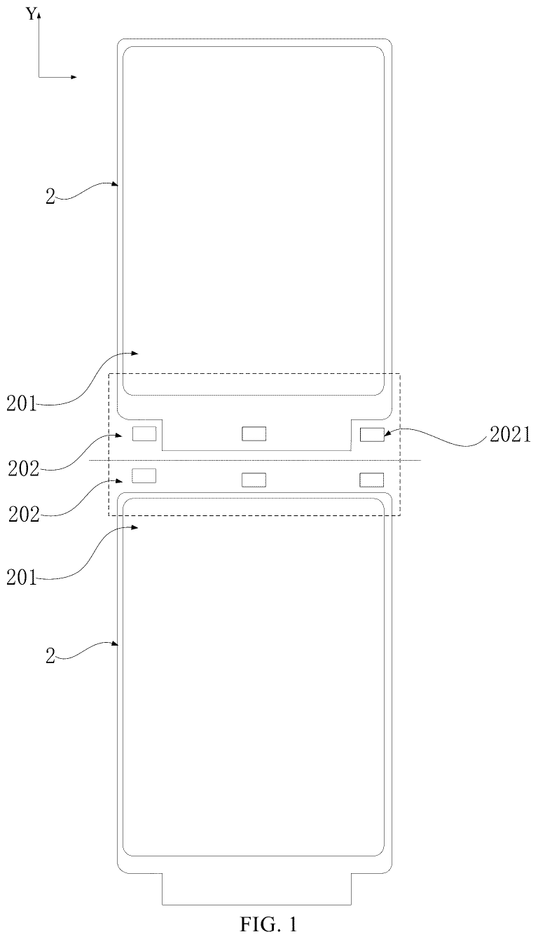

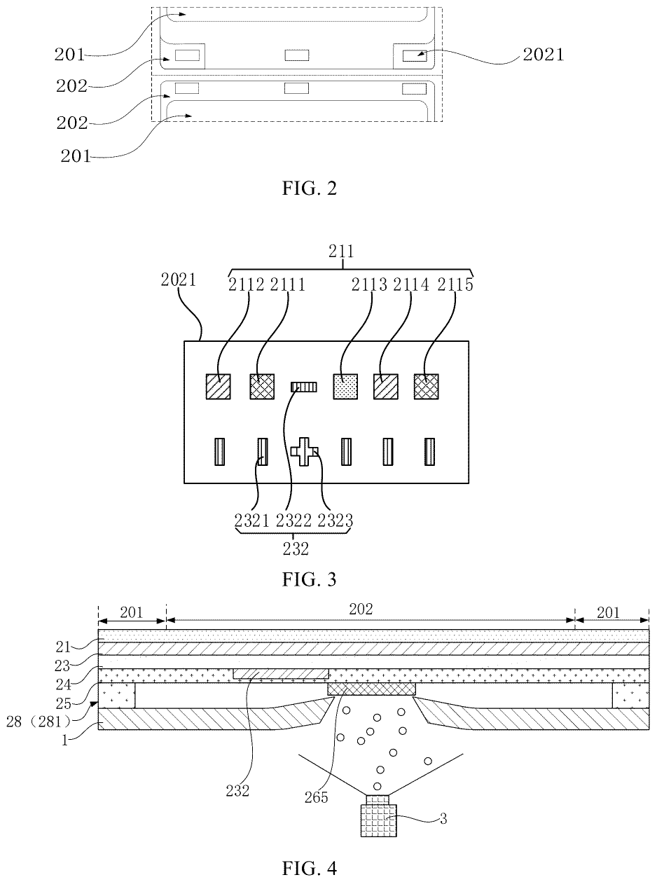

As shown in FIG. 1 and FIG. 2, taking a rectangular display panel as an example, the non-display area 202 of the display panel 2 may include two first sub-non-display areas extending along a first direction and two second sub-non-display areas extending along a second direction. The second sub-non-display area, located at the lower portion of the display panel, is provided with a binding area. The non-display area 202 is provided with multiple identification areas 2021. The identification areas 2021 are provided with a pattern group to be identified. These patterns can be placed in the two first sub-non-display areas, typically in the second sub-non-display area with the binding area. However, in some cases, they may also be placed in the second sub-non-display area. It should be noted that the first direction is the x-direction in FIG. 1, and the second direction is the y-direction in FIG. 1.

As shown in FIG. 3, the pattern group to be identified includes a pattern-to-be-formed area 211. The pattern-to-be-formed area 211 includes a first figure-to-be-formed region 2111, a second figure-to-be-formed region 2112, a third figure-to-be-formed region 2113, a fourth figure-to-be-formed region 2114, and a fifth figure-to-be-formed region 2115 to be. The third figure-to-be-formed region 2113, the fourth figure-to-be-formed region 2114, the fifth figure-to-be-formed region 2115, the first figure-to-be-formed region 2111, and the second figure-to-be-formed region 2112 can be arranged sequentially along the first direction.

The pattern group to be identified further includes an alignment pattern 232. The alignment pattern 232 includes at least one first alignment mark 2321, multiple second alignment marks 2322, and a third alignment mark 2323. The first alignment mark 2321 is arranged along the first direction and is located on the same straight line as the various figure-to-be-formed regions. The multiple second alignment marks 2322 are arranged along a second direction that intersects the first direction, and the multiple second alignment marks 2322 are located on the same straight line as the various figure-to-be-formed regions along the second direction respectively. The third alignment mark 2323 is located at the intersection point of the line containing the first alignment mark 2321 and the line containing the second alignment mark 2322.

Alignment patterns 232 can be set to monitor the positional accuracy of the various sub-pixel light-emitting layers in the non-display area 202. Multiple alignment marks can be used to calibrate the ideal positions of various figure-to-be-formed regions. By monitoring offsets between centers of each light-emitting layer and each auxiliary layer and centers of the alignment marks, the overall offset of the fine metal mask can be estimated, allowing for re-stretching the fine metal mask or compensating for the evaporation process.

There is scratching problem between the fine metal mask and the backplane. As shown in FIG. 4, the display panel includes a backplane. The backplane may include a substrate 20, a driving circuit layer 23, a planarization layer group 24, and a pixel definition layer 25. The driving circuit layer 23 is disposed on one side of the substrate 20, the planarization layer group 24 is disposed on a side of the driving circuit layer 23 facing away from the substrate 20, and the pixel definition layer 25 is disposed on a side of the planarization layer group 24 facing away from the substrate 20. When the pixel layer is deposited on the pixel definition layer 25 by evaporation, the light-emitting functional layer is formed on the pattern-to-be-formed area of the pixel definition layer. The fine metal mask 1 is located on the side of the spacer columns 281 of the spacer layer 28 facing away from the backplane. There is a step difference between the fine metal mask 1 and the pattern-to-be-formed area. The fine metal mask 1 may fluctuate during the evaporation process (displacement in directions perpendicular to and parallel to the backplane), resulting in scratches between the fine metal mask 1 and the backplane, generating particulate contaminants, which affects the identification accuracy of the pixel position accuracy test element group 3.

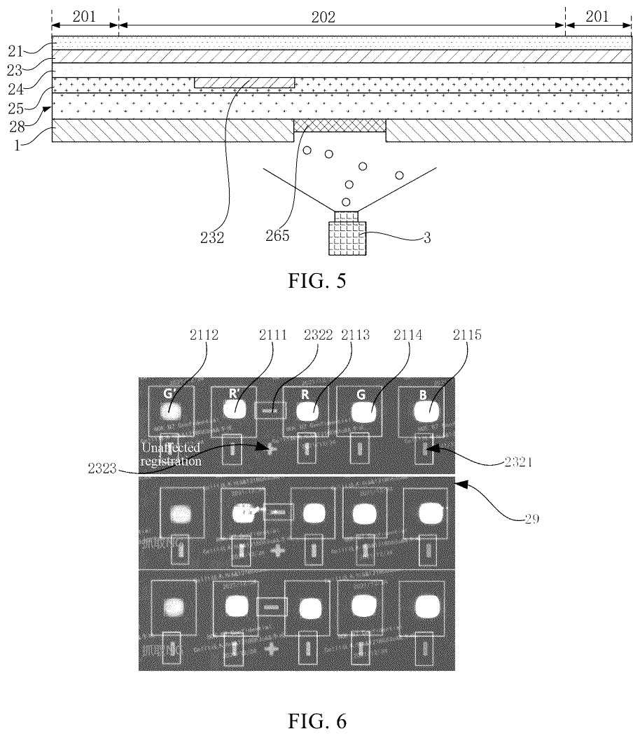

As shown in FIG. 5, to eliminate the step difference between the fine metal mask 1 and the backplane, a spacer layer 28 is provided in the pattern-to-be-formed area. The light-emitting material layer configured to form the sub-pixels is formed on the spacer layer 28, so that the side of the fine metal mask 1 close to the backplane is flush with the pattern-to-be-formed area. However, since the fluctuations of the fine metal mask 1 (displacement in directions perpendicular to and parallel to the backplane) still exist, the fine metal mask 1 still comes into direct contact with the pattern-to-be-formed area, resulting in scratches and poor detection, which can affect the identification accuracy of the pixel position accuracy test element group 3. For an example of a scratch, refer to FIG. 6, where particulate matters are distributed on the backplane 29.

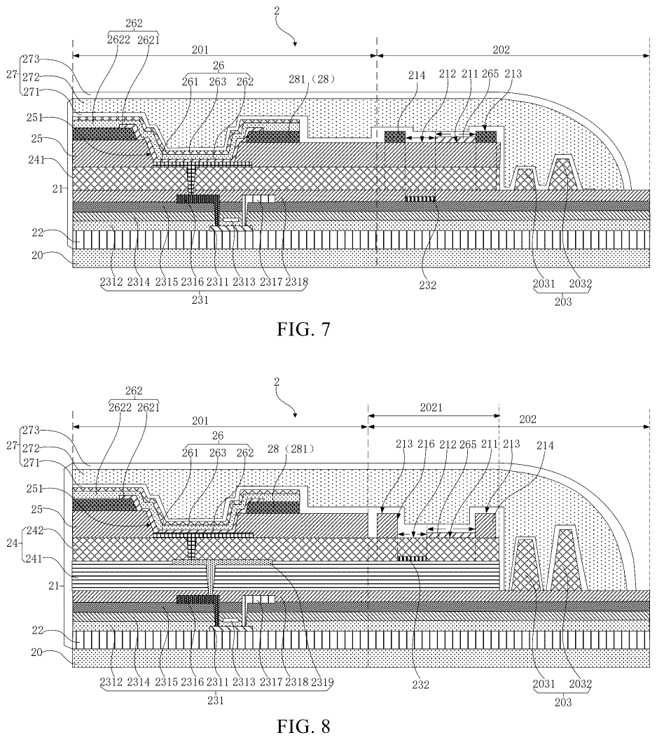

Based on this, embodiments of the present disclosure provide a display panel. As shown in FIG. 7 to FIG. 19, the display panel 2 has a display area 201 and a non-display area 202 located around the periphery of the display area 201. The display panel 2 includes a substrate 20 and a functional layer group 21. The functional layer group 21 is disposed on one side of the substrate 20. The side of the functional layer group 21 facing away from the substrate 20 includes at least one pattern-to-be-formed area 211 and other area. The at least one pattern-to-be-formed area 211 is located in the non-display area, and the other area is located around the periphery of the pattern-to-be-formed area 211. The distance between at least some of the other area and the substrate 20 is greater than the distance between the pattern-to-be-formed area 211 and the substrate 20.

The functional layer group 21 includes at least one pattern-to-be-formed area 211 and other area on the side facing away from the substrate 20. The other area is located around the periphery of the pattern-to-be-formed area, with at least part of the other area being higher than the pattern-to-be-formed area 211. The distance between at least part of the other area and the substrate 20 is greater than the distance between the pattern-to-be-formed area 211 and the substrate 20. This creates a step difference between the other area and the pattern-to-be-formed area 211, preventing the fine metal mask from scratching the pattern-to-be-formed area 211 during fluctuations. This prevents the formation of particles in the pattern-to-be-formed area 211, improves the identification accuracy of the test device, and thus increases the evaporation yield.

It should be noted that the “other area” refer to the area of the display panel 2 other than the pattern-to-be-formed area 211. They can include the non-display area 202 other than the pattern-to-be-formed area 211, or they can include part of the display area 201.

The display panel according to embodiments of the present disclosure will be described in detail below with reference to specific embodiments.

As shown in FIG. 7 to FIG. 10, the display panel 2 includes a substrate 20 and a functional layer group 21 disposed on one side of the substrate 20. The display panel 2 has a display area 201 and a non-display area 202 located around the periphery of the display area 201. The functional layer group 21 includes a drive circuit layer and a pixel layer. The drive circuit layer is disposed on one side of the substrate 20, and the pixel layer is disposed on the side of the drive circuit layer facing away from the substrate 20.

The functional layer group 21 includes a planarization layer group 24 disposed between the drive circuit layer and the pixel layer. The planarization layer group 24 may include a first planarization layer disposed on the side of the drive circuit layer facing away from the substrate 20.

The drive circuit layer may include multiple thin-film transistors 231. The thin-film transistor 231 can be either a top-gate or bottom-gate type. For example, in a case where the thin-film transistor 231 is the top-gate type, the thin-film transistor 231 may include an active layer 2311, a gate insulating layer 2312, a gate electrode 2313, and source/drain metal layers, where:

The active layer 2311 is disposed on one side of the substrate 20 and can be made of polycrystalline silicon, amorphous silicon, or other materials. The active layer 2311 may include a channel region and two doped regions of different doping types located on either side of the channel region.

The gate insulating layer 2312, made of an insulating material such as silicon oxide, etc., covers the active layer 2311 and the substrate 20.

The gate electrode 2313 is located on the side of the gate insulating layer 2312 facing away from the substrate 20 and directly opposite the active layer 2311. Specifically, the projection of the gate electrode 2313 on the substrate 20 is within the projection of the active layer 2311 on the substrate 20. For example, the projection of the gate electrode 2313 on the substrate 20 overlaps with the projection of the channel region of the active layer 2311 on the substrate 20.

The thin-film transistor 231 further includes an interlayer insulating layer 2314, which covers the gate electrode 2313 and the gate insulating layer 2312. The thin-film transistor 231 further includes an interlayer dielectric layer 2315, which is located on the side of the interlayer insulating layer 2314 facing away from the substrate 20. Both the interlayer insulating layer 2314 and the interlayer dielectric layer 2315 are made of insulating materials, but the materials of the interlayer insulating layer 2314 and the interlayer dielectric layer 2315 may be different.

The source/drain metal layer may include a first source/drain metal layer, disposed on the surface of the interlayer dielectric layer 2315 facing away from the substrate 20. The first source/drain metal layer includes a first source electrode 2316 and a drain electrode 2317, which are connected to the active layer 2311. For example, the first source electrode 2316 and the drain electrode 2317 are connected to two doped regions of the corresponding active layer 2311 through vias.

A protective layer 2318 is disposed on the side of the first source electrode 2316 facing away from the substrate 20, covering the first source electrode 2316 and the drain electrode 2317. A first planarization layer 24 is disposed on the side of the first source/drain metal layer facing away from the substrate 20, covering the protective layer 2318. The surface of the first planarization layer 24 facing away from the substrate 20 is flat.

The source/drain metal layer may further include a second source/drain metal layer, which includes a second source electrode 2319. A second planarization layer 242 is provided on the side of the second source electrode 2319 facing away from the substrate 20. The second planarization layer covers the second source electrode 2319 and the first planarization layer 24. The second source electrode 2319 is connected to the first source electrode 2316 through a via.

It should be noted that a buffer layer 22 is typically provided between the substrate 20 and the driver circuit layer.

A pixel definition layer 25 and a pixel layer 26 may be provided on the side of the driver backplane facing away from the substrate 20. The pixel definition layer 25 has multiple pixel openings 251. The pixel layer 26 includes multiple sub-pixels, and the multiple sub-pixels are located within the multiple pixel openings 251 respectively. The multiple sub-pixels are arranged in an array on the side of the driver backplane facing away from the substrate 20. Specifically, the sub-pixels may be located on the side of the first planarization layer 24 or the second planarization layer facing away from the substrate 20. It should be noted that the sub-pixels may include red, green, or blue sub-pixels, depending on the color of the light emitted.

Each subpixel can include a first electrode 261, a light-emitting layer group 262, and a second electrode 263. The first electrode 261 is located on the surface of the driver backplane facing away from the substrate 20. The light-emitting layer group 262 is located on the surface of the first electrode 261 facing away from the substrate 20. The second electrode 263 is located on the surface of the light-emitting layer group 262 facing away from the substrate 20. The first and second electrodes 261, 263 drive the pixel layer to emit light, thereby displaying an image.

The first electrode 261 is connected to either the first source electrode 2316 or the second source electrode 2319. When the thin-film transistor 231 includes only the first source electrode 2316, the first electrode 261 is connected to the first source electrode 2316, and a pixel definition layer 25 is provided to cover the first electrode 261 and the first planarization layer 24. When the thin-film transistor 231 further includes the second source electrode 2319, the first electrode 261 is connected to the second source electrode 2319, and a pixel definition layer 25 is provided to cover the first electrode 261 and the fourth planarization layer.

The second electrode 263 can serve as a cathode, and the first electrode 261 can serve as an anode. A signal applied to the first electrode 261 can drive the light-emitting layer group 262 to emit light. The specific light-emitting principle will not be detailed here.

The light-emitting layer group 262 can include an electroluminescent organic light-emitting material. For example, the light-emitting layer group 262 can include a patterned layer 2621 and a common layer 2622 stacked on the first electrode 261. The patterned layer 2621 can include a first patterned portion and a second patterned portion. The first patterned portion is located on the side of the first electrode 261 facing away from the substrate 20, and the second patterned portion is located on the side of the pixel definition layer 25 facing away from the substrate 20. The orthographic projection of the common layer 2622 on the substrate 20 covers the orthographic projections of each first electrode 261 on the substrate 20 and the portion of the pixel definition layer 25 located between any two adjacent first electrodes 261.

The patterned layer 2621 may include an auxiliary layer and a light-emitting layer. The auxiliary layer typically includes a hole injection layer, a hole transport layer, an electron transport layer, and an electron injection layer. The common layer 2622 is typically a charge generation layer. A patterned area is typically provided on a mask, and processes such as evaporation are used to form the auxiliary layers for subpixels of different colors and the light-emitting layers for sub-pixels of different colors.

In addition, the display panel 2 of the present disclosure may further include an encapsulation layer 27. The encapsulation layer 27 is disposed on the side of the pixel layer 26 facing away from the substrate 20, thereby encapsulating the pixel layer 26 and protecting it from water and oxygen corrosion. The encapsulation layer 27 may be a single-layer or multi-layer structure, and the material of the encapsulation layer 27 may include organic or inorganic materials, which are not limited thereto.

In this embodiment, the encapsulation layer 27 includes a first inorganic encapsulation layer 271, an organic encapsulation layer 272, and a second inorganic encapsulation layer 273. The first inorganic encapsulation layer 271 is disposed on the side of the pixel layer 26 facing away from the substrate 20, the organic encapsulation layer 272 is disposed on the side of the first inorganic encapsulation layer 271 away from the substrate 2020, and the second inorganic encapsulation layer 273 is disposed on the side of the organic encapsulation layer 272 facing away from the substrate 20. The first inorganic encapsulation layer 271 and the second inorganic encapsulation layer 273 can be formed by vapor deposition, while the organic encapsulation layer 272 can be formed by inkjet printing and leveling.

Because liquid organic encapsulation materials flow, they are prone to overflow. To prevent overflow, especially at the lower frame, a dam has traditionally been provided in the non-display area 202, away from the display area 201, to provide a barrier. The cross-sectional shape of the dam can be rectangular as shown in the figure, or trapezoidal. The dam has a sidewall close to the display area 201, and at least this sidewall is sloped, but this is not limited here.

In the non-display area 202, multiple dams 203 are provided, successively farther away from the display area 201. The multiple dams 203 can include a first dam 2031 and a second dam 2032. The first dam 2031 surrounds the display area 201, while the second dam 2032 surrounds the first dam 2031.

As shown in FIG. 7, the pattern-to-be-formed area 211 is located on the side of the pixel definition layer away from the substrate 20. The functional layer group 21 also includes other area located on the periphery of the pattern-to-be-formed area 211 on the side facing away from the substrate 20. The other area includes an alignment pattern area 212. The alignment pattern area 212 is located in the non-display area 202 and adjacent to the pattern-to-be-formed area 211. The alignment pattern area 212 is also located on the side of the pixel definition layer away from the substrate 20.

The alignment pattern area 212 has an alignment opening, within which each alignment mark of the alignment pattern 232 is located. As shown in the figure, the second alignment mark 2322 and the third alignment mark 2323 are both located within the alignment pattern area 212. It is understood that the orthographic projection of the alignment pattern 232 on the substrate 20 is at least partially located within the orthographic projection of the alignment pattern area 212 on the substrate 20. The alignment pattern 232 can be located on the side of the second planarization layer away from the substrate 20 and can be formed from the same material and on the same layer as the first electrode 261.

The other area further includes a support region 213, which is located on the periphery of the alignment pattern area 212 and includes a support portion 214. The support portion 214 is located on the spacer layer 28 and is formed on the same layer and from the same material as the spacer pillar 281. The support area 213 is located on the side of the support portion 214 away from the substrate 20. The distance between the support area 213 and the substrate 20 is greater than the distance between the pattern-to-be-formed area 211 and the substrate 20, and the distance between the support area 213 and the substrate 20 is also greater than the distance between the alignment pattern area 212 and the substrate 20. When the fine mask contacts the spacer pillars 281, the opening in the figure-to-be-formed region will not scratch the figure-to-be-formed region.

As shown in FIG. 8, unlike FIG. 7, the alignment pattern 232 is provided on the same layer as the first or second source electrode 2319. That is, the alignment pattern 232 can be provided between the interlayer dielectric layer and the first planarization layer, or between the first and second planarization layers. A second opening 216 is provided in the non-display area 202. The second opening 216 penetrates the pixel definition layer, exposing the second planarization layer. Both the pattern-to-be-formed area 211 and the alignment pattern area 212 are located within the second opening 216. The remaining portion of the pixel definition layer in the non-display area 202 serves as the support portion 214.

It can be understood that the pattern-to-be-formed area 211 and the alignment pattern area 212 are both located on the side of the second planarization layer away from the substrate 20, while the support area 213 is located on the side of the pixel definition layer away from the substrate 20. Therefore, the distance between the support area 213 and the substrate 20 is greater than the distance between the figure-to-be-formed region and the substrate 20. This creates a step difference between the support area 213 and the figure-to-be-formed region. When the fine mask contacts the spacer pillars 281, the opening in the figure-to-be-formed region similarly does not scratch the figure-to-be-formed region.

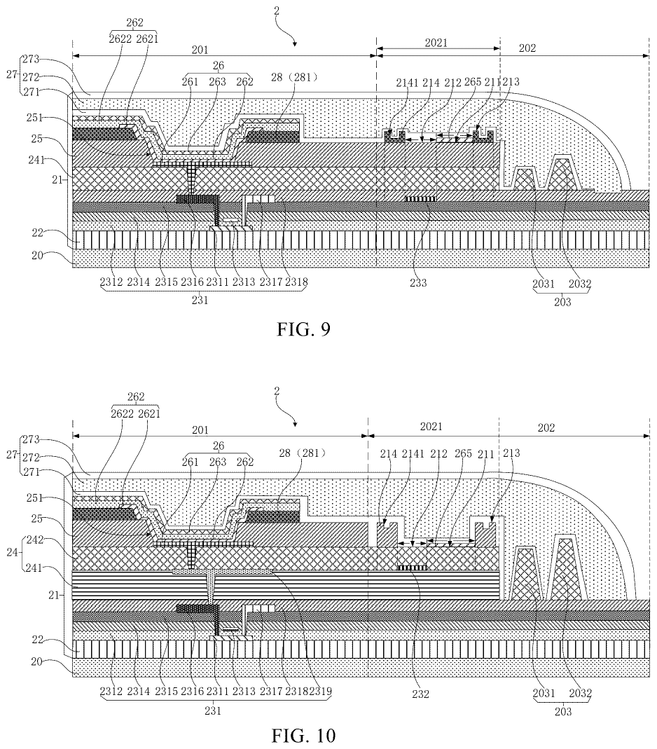

As shown in FIG. 9 and FIG. 10, typically, the wider the support portion 214, the greater its support strength. To ensure the width of the support portion 214 while minimizing the contact area between the support portion 214 and the fine mask, both the display panel 2 in FIG. 7 and the display panel 2 in FIG. 8 may include a first groove 2141 on the side of the support portion 214 facing away from the substrate 20. The first groove 2141 extends in the same direction as the support portion 214. The support portion 214 may include one or more first grooves 2141.

The pixel layer 26 in the display area 201 typically includes multiple red sub-pixels, multiple green sub-pixels, and multiple blue sub-pixels. The blue sub-pixels may include a blue sub-pixel light-emitting layer, the red sub-pixels may include a red sub-pixel auxiliary layer and a red sub-pixel light-emitting layer, and the green sub-pixels may include a green sub-pixel auxiliary layer and a green sub-pixel light-emitting layer.

The pixel layer 26 in the display area 201 is typically formed layer by layer by evaporation on the driver circuit layer using the mask 1. When forming pixel layer 26 on the driver circuit layer, the blue sub-pixel light-emitting layer is typically evaporated first, followed by the red sub-pixel auxiliary layer, then the red sub-pixel light-emitting layer, then the green sub-pixel auxiliary layer, and finally the green sub-pixel light-emitting layer, forming red, green, and blue sub-pixels.

The red pixel auxiliary layer is located on the side of the red pixel light-emitting layer close to the driver circuit layer and serves to conduct light when the red pixel is emitting. The green pixel auxiliary layer is located on the side of the green pixel light-emitting layer close to the driver backplane and serves to conduct light when the green pixel is emitting. Due to the blue pixel material, auxiliary pixels are not required to conduct light when the blue pixel is emitting, so a blue pixel auxiliary layer is not required.

Because the red sub-pixel light-emitting layer, green sub-pixel light-emitting layer, blue sub-pixel light-emitting layer, the red sub-pixel auxiliary layer and green sub-pixel auxiliary layer are evaporated in different evaporation chambers, and thus the evaporation accuracies of these layers are typically monitored. For this reason, a light-emitting functional layer 265 is typically formed within each figure-to-be-formed region of the non-display area 202. The light-emitting functional layer 265 can be formed from the same material and on the same layer as the patterned layer 2621.

A fine mask is configured to define a light-emitting functional pattern on the side of the drive circuit layer facing away from the substrate 20. The light-emitting functional pattern includes multiple light-emitting functional layers 265 spaced apart. Light-emitting layers and auxiliary layers for various sub-pixels are formed within each light-emitting functional layer 265. A spacer layer 28 can be provided between the pixel layer and the pixel definition layer. The spacer layer 28 includes multiple spacer pillars 281. The spacer pillars 281 are positioned around the pixel openings 251 to support the fine mask during evaporation.

The light-emitting functional layer 265 may include a first figure to be formed, a second figure to be formed, a third figure to be formed, a fourth figure to be formed, and a fifth figure to be formed. The first figure to be formed may be provided on the same layer and with the same material as the red sub-pixel light-emitting layer, the second figure to be formed may be provided on the same layer and with the same material as the green sub-pixel light-emitting layer, the third figure to be formed may be provided on the same layer and with the same material as the blue sub-pixel light-emitting layer, the fourth figure to be formed may be provided on the same layer and with the same material as the red sub-pixel auxiliary layer, and the fifth figure to be formed may be provided on the same layer and with the same material as the green sub-pixel auxiliary layer. The first, second, third, fourth, and fifth figures to be formed are arranged to be non-overlapping with each other.

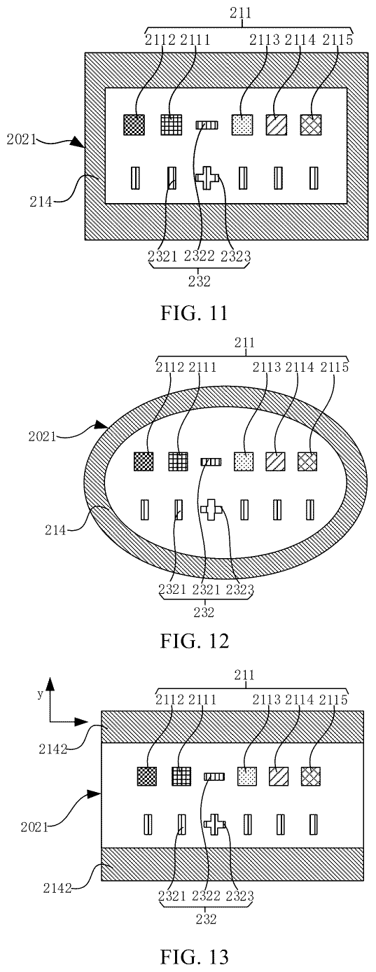

As shown in FIG. 11 to FIG. 16, multiple figure-to-be-formed regions are provided, and the multiple figure-to-be-formed regions are arranged sequentially along a first direction. The multiple figure-to-be-formed regions are divided into the figure-to-be-formed region of the auxiliary layer and the figure-to-be-formed region of the light-emitting layer. The figure-to-be-formed region of the auxiliary layer includes the figure-to-be-formed region of the red sub-pixel auxiliary layer, the figure-to-be-formed region of the green sub-pixel auxiliary layer, the figure-to-be-formed region of the red sub-pixel light-emitting layer, the figure-to-be-formed region of the green sub-pixel light-emitting layer, and the figure-to-be-formed region of the blue sub-pixel light-emitting layer.

A red sub-pixel auxiliary layer is formed in the figure-to-be-formed region of the red sub-pixel auxiliary layer, a green sub-pixel auxiliary layer is formed in the figure-to-be-formed region of the green sub-pixel auxiliary layer, a red sub-pixel light-emitting layer is formed in the figure-to-be-formed region of the red sub-pixel light-emitting layer, a green sub-pixel light-emitting layer is formed in the figure-to-be-formed region of the green sub-pixel light-emitting layer, and a blue sub-pixel light-emitting layer is formed in the figure-to-be-formed region of the blue sub-pixel light-emitting layer.

By monitoring the evaporation positions of the red sub-pixel light-emitting layer, green sub-pixel light-emitting layer, blue sub-pixel light-emitting layer, red sub-pixel auxiliary layer, and green sub-pixel auxiliary layer in the non-display area 202, the evaporation positions of the red sub-pixel light-emitting layer, green sub-pixel light-emitting layer, blue sub-pixel light-emitting layer, red sub-pixel auxiliary layer, and green sub-pixel auxiliary layer in the display area 201 can be determined.

As shown in FIG. 6, the figure-to-be-formed region of the red sub-pixel auxiliary layer is a first figure-to-be-formed region 2111, the figure-to-be-formed region of the green sub-pixel auxiliary layer is a second figure-to-be-formed region 2112, the figure-to-be-formed region of the red sub-pixel light-emitting layer is a third figure-to-be-formed region 2113, the figure-to-be-formed region of the green sub-pixel light-emitting layer is a fourth figure-to-be-formed region 2114, and the figure-to-be-formed region of the blue sub-pixel light-emitting layer is a fifth figure-to-be-formed region 2115.

Alignment marks 234 include at least one first alignment mark 2321 arranged along the first direction, second alignment marks 2322 arranged along the second direction and corresponding one-to-one with the five figure-to-be-formed regions, and third alignment marks 2323 aligned with the first and second alignment marks 2321 and 2322. The first alignment mark 2321 is located between the fifth figure-to-be-formed region 2115 and the first figure-to-be-formed region 2111. Five second alignment marks 2322 are located along the second direction on the same side of the first figure-to-be-formed region 2111, the second figure-to-be-formed region 2112, the third figure-to-be-formed region 2113, the fourth figure-to-be-formed region 2114, and the fifth figure-to-be-formed region 2115. The third alignment mark 2323 is located on the same straight line as the five second alignment marks 2322 along the second direction. The third alignment mark 2323 is located between the first alignment mark 2321 corresponding to the fifth figure-to-be-formed region 2115 and the first alignment mark 2321 corresponding to the first figure-to-be-formed region 2111.

The non-display area 202 includes an identification area 2021. The alignment pattern 232 and the light-emitting functional layer 265 of the pattern-to-be-formed area 211 form a pattern group to be identified. The pattern group to be identified is located within the identification area 2021. The support portion 214 surrounds the pattern group to be identified. The support portion 214 is located outside or inside the identification area 2021. Referring to FIG. 1 and FIG. 2, to ensure monitoring accuracy, the display panel 2 includes multiple pattern groups to be identified. Each of these groups is individually identified by the test element group. The distance between the edge of the pattern-to-be-formed area 211 and the edge of the display area 201 is less than 2 mm.

When the support portion 214 is within the identification area 2021, to ensure effective support while minimizing the impact on the identification process, the dimensions of the support portion 214 along the first direction and the second direction are unequal. The first direction is parallel to the surface of the substrate 20, and the second direction is perpendicular to the surface of the substrate 20. The dimension of the support portion 214 along the first direction ranges from 50 μm to 100 μm.

When the support portion 214 is outside the identification area 2021, the closer the support portion 214 is to the identification area 2021, the better the support effect. To ensure effective support for the identification area 2021, the support portion 214 should not be too far from the identification area 2021. Generally, the distance between the support portion 214 and the edge of the identification area 2021 is less than 1 mm, which can be adjusted according to actual needs.

The dimensions of the support portion 214 along the first direction and the second direction are unequal. The dimensions of the support portion 214 along the first direction range from 50 μm to 100 μm. Both the first and second directions lie on the surface of the substrate 20, with the second direction perpendicular to the first direction.

It is important to emphasize that the distance between the support area 213 and the substrate 20 is greater than the distance between the pattern-to-be-formed area 211 and the substrate 20. It is understood that the height difference between the support area 213 and the pattern-to-be-formed area 211 ranges from 1 to 2 μm to ensure that the support portion 214 provides protective support.

As shown in FIG. 11 and FIG. 12, the support portion 214 is a continuous and closed structure. The outline of the orthographic projection of the support portion 214 on the substrate 20 can be elliptical, circular, rectangular, or other polygonal shapes.

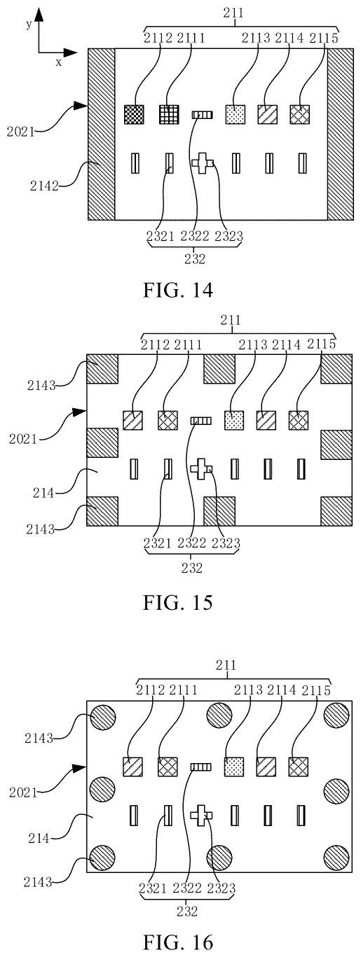

As shown in FIG. 13 and FIG. 14, the support portion 214 can also be a non-enclosed, fully surrounding structure. The support portion 214 includes at least one set of support segments 2142. One set of the support segments includes two support segments 2142. The two support segments 2142 are arranged parallel to opposite sides of the identification area 2021. The two support segments 2142 can be located on two sides of the identification area 2021 extending in the first direction or the two sides of the identification area 2021 extending in the second direction.

As shown in FIG. 15 and FIG. 16, the support portion 214 further includes multiple support blocks 2143 arranged along the contour of the identification area 2021. These multiple support blocks 2143 provide support around the figure-to-be-formed regions. The larger the area of the support blocks 2143, the better the support effect. The support block 2143 is a rectangular parallelepiped, cylindrical, or prism. The orthographic projection of the support block 2143 on the substrate 20 is rectangular, circular, or polygonal. When the support block 2143 is a rectangular parallelepiped, the orthographic projection of the support block 2143 on the substrate 20 is a 30×30 μm rectangle.

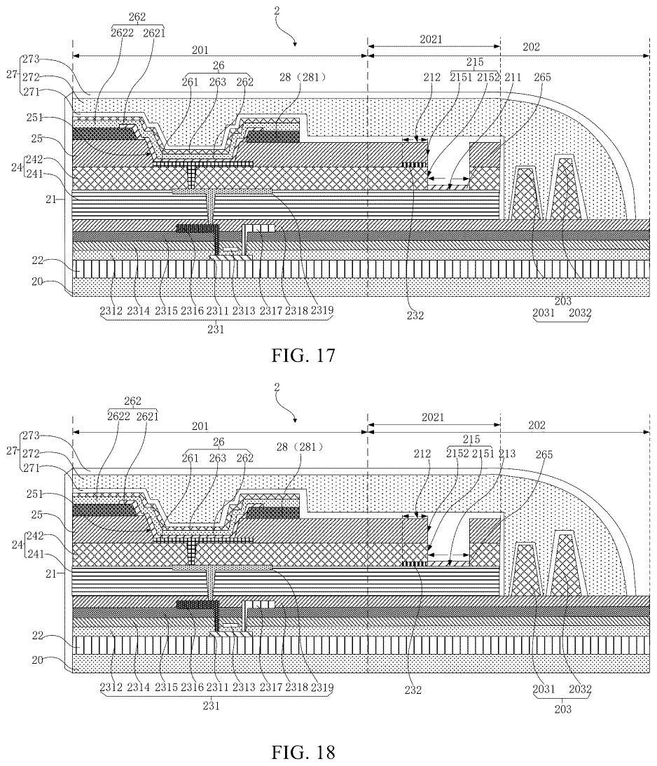

As shown in FIG. 17 and FIG. 18, the difference from FIG. 7 is that the display panel 2 does not have a support portion 214. Instead, the non-display area 202 is provided with a first opening 215. The first opening 215 passes through at least a portion of the pixel definition layer. The first opening 215 may include a first opening segment 2151 located in the pixel definition layer, or may include a first opening segment 2151 located in the pixel definition layer and a second opening segment 2152 located in the second planarization layer. The orthographic projection of the first opening segment 2151 on the substrate 20 coincides with the orthographic projection of the second opening segment 2152 on the substrate 20.

The pattern-to-be-formed area 211 is located within the first opening 215. The bottom of the first opening 215 is the figure-to-be-formed region. Therefore, the figure-to-be-formed region is located on the side of the first or second planarization layer away from the substrate 20. The alignment pattern area 212 is located on the surface of the pixel definition layer away from the substrate 20. It is understood that the distance between the alignment pattern area 212 and the substrate 20 is greater than the distance between the figure-to-be-formed region and the substrate 20. This creates a step between the alignment pattern area 212 and the figure-to-be-formed region. When the fine mask contacts the spacer pillars 281, the opening in the figure-to-be-formed region will not scratch the figure-to-be-formed region.

In FIG. 17, the alignment pattern 232 can be located on the side of the second planarization layer away from the substrate 20. The alignment pattern 232 can be provided on the same layer and with the same material as the first electrode 261. In FIG. 18, the alignment pattern 232 is provided on the same layer and with the same material as the second source electrode 2319, meaning that the alignment pattern 232 is located between the first and second planarization layers. The alignment pattern 232 can also be provided on the same layer and with the same material as the first source electrode, meaning that the alignment pattern 232 can be located between the interlayer dielectric layer and the first planarization layer.

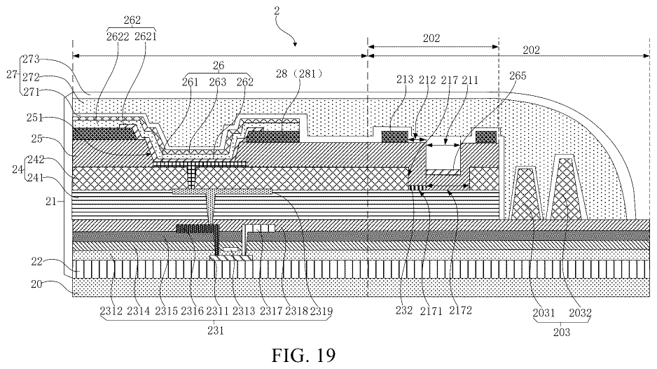

As shown in FIG. 19, the difference from the previous figure lies in that the second planarization layer is provided with a third opening 217, and the third opening 217 passes through the second planarization layer, exposing the first planarization layer. The area of the first planarization layer located at the third opening 217 includes a first sub-opening area 2171 and a second sub-opening area 2172. The alignment pattern 232 is provided in the first sub-opening area 2171, while the pixel definition layer covers the second sub-opening area 2172. The alignment pattern 232 is provided in the first sub-opening area 2171. The pixel definition layer covers the second sub-opening area 2172, as well as the alignment pattern 232 and the side of the second planarization layer facing away from the substrate 20. The orthographic projection of the alignment pattern area 212 on the pixel definition layer overlaps with the orthographic projection of the first sub-opening area 2171 on the pixel definition layer, and the orthographic projection of the pattern-to-be-formed area 211 on the pixel definition layer overlaps with the orthographic projection of the second sub-opening area 2172 on the pixel definition layer. It should be noted that the second sub-opening refers to the area within the first sub-opening area 2171 excluding the first sub-opening area 2171.

It should be noted that the identification area 2021 can also be located on the side of the second dam 2032 in the non-display area 202 facing away from the display area 201. It is understood that the identification area 2021 can be located within the non-display area 202.

As shown in FIG. 7 and FIG. 9, when the light-emitting functional layer 265 is located on the side of the pixel definition layer facing away from the substrate, the distance between the side of the light-emitting functional layer 265 facing away from the substrate and the substrate is less than the distance between the side of the support portion facing away from the substrate and the substrate. The distance between the side of the light-emitting functional layer 265 facing away from the substrate and the side of the second patterned portion facing away from the substrate is 0 mm, and the distance between the side of the light-emitting functional layer 265 facing away from the substrate and the side of the first patterned portion facing away from the substrate ranges from 1 to 2 mm.

As shown in FIG. 8 and FIG. 10, when the light-emitting functional layer 265 is located within the second opening, the light-emitting functional layer 265 can be located on the side of the second planarization layer facing away from the substrate. The distance between the side of the light-emitting functional layer 265 facing away from the substrate and the substrate is smaller than the distance between the side of the pixel definition layer facing away from the substrate and the substrate. The thickness of the pixel definition layer is between 1 and 2 mm. Therefore, the distance between the side of the light-emitting functional layer 265 facing away from the substrate and the side of the second patterned portion facing away from the substrate is −1 to −2 mm, and the distance between the side of the light-emitting functional layer 265 facing away from the substrate and the side of the first patterned portion facing away from the substrate is 0 mm.

As shown in FIG. 17 and FIG. 18, when formed within the first opening, the light-emitting functional layer 265 can be located on the side of the protective layer away from the substrate, on the side of the first planarization layer away from the substrate, or on the side of the second planarization layer away from the substrate. The distance between the side of the light-emitting functional layer 265 away from the substrate and the substrate is smaller than the distance between the side of the part of the pixel definition layer outside the first opening away from the substrate and the substrate. The thicknesses of the first planarization layer, the second planarization layer, and the pixel definition layer range from 1 to 2 mm. Therefore, the distance between the side of the light-emitting functional layer 265 away from the substrate and the side of the second patterned portion away from the substrate is −1 to −6 mm, and the distance between the side of the light-emitting functional layer 265 away from the substrate and the side of the first patterned portion away from the substrate is −1 to −4 mm.

As shown in FIG. 19, when formed within the third opening, the light-emitting functional layer 265 is located on the side of the pixel definition layer away from the substrate. The pixel definition layer can be located on the side of the protective layer away from the substrate, on the side of the first planarization layer away from the substrate, or on the side of the second planarization layer away from the substrate. The distance between the side of the light-emitting functional layer 265 away from the substrate and the substrate is smaller than the distance between the side of the part of the pixel definition layer outside the third opening away from the substrate and the substrate. The distance between the side of the light-emitting functional layer 265 away from the substrate and the side of the second patterned portion away from the substrate is −1 to −4 mm, and the distance between the side of the light-emitting functional layer 265 away from the substrate and the side of the first patterned portion away from the substrate is −2 to 0 mm.

The embodiment of the present disclosure also provides a display device. The display device may include any of the display panels described above. The specific structure and beneficial effects of the display panel have been described in detail above and are therefore not further elaborated here.

It should be noted that, in addition to the display panel, the display device further includes other necessary components and elements, such as a circuit board and power cord. Those skilled in the art may supplement these components based on the specific requirements of the display device, and these will not be detailed here.

When the display panel is as shown in the figure, the display device can be a traditional electronic device, such as a mobile phone, a computer, a television, and a camcorder, or it can be an emerging wearable device, such as a virtual reality device and an augmented reality device, all of which are not listed here.

Those skilled in the art will readily identify other embodiments of the present disclosure after considering the specification and practicing the disclosure herein. This application is intended to cover any variations, uses, or adaptations of the present disclosure that follow the general principles of the present disclosure and include common knowledge or customary techniques in the art not disclosed herein. The specification and examples are to be considered as illustrative only; the true scope and spirit of the present disclosure are indicated by the appended claims.

1. A display panel comprising a display area and a non-display area peripherally surrounding the display area, wherein the display panel comprises:
a substrate; and
a functional layer group disposed on a side of the substrate, wherein the functional layer group comprises at least one pattern-to-be-formed area and other area on a side away from the substrate, the at least one pattern-to-be-formed area is located in the non-display area, the other area peripherally surrounds the pattern-to-be-formed area, and a distance between at least part of the other area and the substrate is greater than a distance between the pattern-to-be-formed area and the substrate.

2. The display panel according to claim 1, wherein the functional layer group comprises:
a planarization layer group comprising a first planarization layer and a second planarization layer, wherein the first planarization layer is disposed on a side of the substrate, and the second planarization layer is located on a side of the first planarization layer away from the substrate;
a first electrode disposed on a side of the planarization layer group away from the substrate; and
a pixel definition layer disposed on a side of the first electrode away from the substrate, wherein the pixel definition layer is provided with a pixel opening, and the pixel opening exposes the first electrode.

3. The display panel according to claim 2, wherein the other area comprises an alignment pattern area, the alignment pattern area is located in the non-display area and adjacent to the pattern-to-be-formed area, the functional layer group comprises an alignment pattern, an orthographic projection of the alignment pattern on the substrate is at least partially located within an orthographic projection of the alignment pattern area on the substrate.

4. The display panel according to claim 3, wherein the other area further comprises a support area, the support area peripherally surrounds the alignment pattern area, a distance between the support area and the substrate is greater than a distance between the pattern-to-be-formed area and the alignment pattern area and the substrate.

5. The display panel according to claim 3, wherein the alignment pattern and the first electrode are formed on the same layer and with the same material.

6. The display panel according to claim 3, wherein the functional layer group further comprises a spacer layer, the spacer layer is located on a side of the pixel definition layer away from the substrate, the spacer layer comprises a support portion, the pattern-to-be-formed area is located on a side of the pixel definition layer away from the substrate, and the support area is located on a side of the support portion away from the substrate.

7. The display panel according to claim 3, wherein the functional layer group is provided with a first opening in the non-display area, the first opening at least partially passes through the pixel definition layer, the pattern-to-be-formed area is located within the first opening, and the alignment pattern area is located on a surface of the pixel definition layer away from the substrate.

8. The display panel according to claim 7, wherein the first opening comprises a first opening segment passing through the pixel definition layer, or a first opening segment passing through the pixel definition layer and a second opening segment passing through the second planarization layer, an orthographic projection of the first opening segment on the substrate coincides with an orthographic projection of the second opening segment on the substrate.

9. The display panel according to claim 4, wherein the functional layer group is provided with a second opening in the non-display area, the second opening at least partially passes through the pixel definition layer, the pattern-to-be-formed area and the alignment pattern area are both located within the second opening, and the support area is located on a side of the pixel definition layer away from the substrate.

10. The display panel according to claim 9, wherein the functional layer group further comprises a source/drain metal layer, the source/drain metal layer is located between the first planarization layer and the substrate, and/or between the first planarization layer and the second planarization layer, and the alignment pattern is formed on the same layer and with the same material as the source/drain metal layer.

11. The display panel according to claim 3, wherein the functional layer group is provided with a third opening in the non-display area, the third opening at least partially passes through the second planarization layer, the pattern-to-be-formed area and the alignment pattern area are both located within the third opening, the third opening comprises a first sub-opening area and a second sub-opening area, the alignment pattern is located in the first sub-opening area, the pixel definition layer covers the second sub-opening area, and covers the alignment pattern and a side of the second planarization layer away from the substrate, an orthographic projection of the alignment pattern area on the pixel definition layer overlaps with an orthographic projection of the first sub-opening area on the pixel definition layer, and an orthographic projection of the pattern-to-be-formed area on the pixel definition layer overlaps with an orthographic projection of the second sub-opening area on the pixel definition layer.

12. The display panel according to claim 6, wherein the non-display area comprises an identification area, the alignment pattern and the pattern-to-be-formed area constitute a pattern group to be identified, the pattern group to be identified is located within the identification area, and the support portion is disposed around the pattern group to be identified, and the support portion is located outside or within the identification area.

13. (canceled)

14. The display panel according to claim 6, wherein a dimension of the support portion along a first direction is unequal to a dimension of the support portion along a second direction, the first direction and the second direction both are located on a surface of the substrate, and the second direction is perpendicular to the first direction.

15-16. (canceled)

17. The display panel according to claim 12, wherein the support portion is provided with at least one first groove, and the first groove extends in the same direction as the support portion.

18. The display panel according to claim 12, wherein the support portion is a continuous and closed structure, and an orthographic projection of the support portion on the substrate is an elliptical, circular, or polygonal shape.

19. The display panel according to claim 12, wherein the support portion comprises at least one set of support segments, one set of support segments comprises two support segments, and the two support segments are arranged parallel to opposite sides of the identification area.

20. The display panel according to claim 12, wherein the support portion comprises a plurality of support blocks, the plurality of support blocks are distributed along an outline of the identification area.

21. (canceled)

22. The display panel according to claim 3, wherein the pattern-to-be-formed area comprises multiple figure-to-be-formed regions, the multiple figure-to-be-formed regions are arranged sequentially along a first direction, and the alignment pattern comprises:
at least one first alignment mark, arranged along the first direction and located on the same straight line with the multiple figure-to-be-formed regions;
a plurality of second alignment marks, arranged along a second direction, wherein the second direction intersects the first direction, and the multiple second alignment marks are located on the same straight line with the multiple figure-to-be-formed regions along the second direction respectively; and
a third alignment mark, wherein the third alignment mark is arranged at an intersection point of a line containing the first alignment mark and a line containing the second alignment mark.

23. The display panel according to claim 12, wherein the display panel comprises multiple pattern groups to be identified, all of the multiple pattern groups to be identified are located in the display area.

24. The display panel according to claim 1, wherein a light-emitting functional layer is provided on a side of each of the figure-to-be-formed regions away from the substrate, and a distance between at least part of the other area and the substrate is greater than a distance between the light-emitting functional layer and the substrate.

25. (canceled)
